(19) United States
(12) Patent Application Publication
(10) Pub. No.: US 2004/0040739 A1
(43) Pub. Date: Mar. 4, 2004

(54) Multilayer wiring board and method of manufacturing the same

(76) Inventors: Eiji Yoshimura, Okaya-shi (JP); Masao Okubo, Amagasaki-shi (JP); Kazumasa Okubo, Amagasaki-shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 10/234,669

(22) Filed: Sep. 3, 2002

(51) Int. Cl. H05K 1/03

(52) U.S. Cl. 174/255

(57) ABSTRACT

A multilayer wiring board is manufactured wherein an intermediate wiring layer having a signal pattern is formed on an upper side of a lower shielding layer via an insulating layer, and an upper shielding layer is then formed on an upper side of the intermediate wiring layer via an insulating layer, by a method including forming the lower shielding layer having a lower shielding portion under a portion in which the signal pattern is to be formed, forming a lower metal wall erected from the lower shielding portion under both sides of the portion in which the signal pattern is to be formed, and forming the insulating layer for exposing the lower metal wall and covering the lower shielding layer.

### BACKGROUND OF THE INVENTION

1. Field of the Invention

The present invention relates to a multilayer wiring board having a shield structure comprising a signal pattern and a cylindrical shielding portion formed there around and a method of manufacturing the same, and more particularly to a multilayer wiring board having an excellent high frequency characteristic and a great noise resistance and a method of manufacturing the same.

2. Description of the Related Art

In recent years, an increase in a density has been highly required for a wiring board because of a reduction in the size and weight of an electronic apparatus, and a multilayer structure for wiring layers has been formed as a countermeasure. A multilayer wiring board has mainly been manufactured by a build-up method of sequentially repeating the formation of an insulating layer and a wiring pattern.

On the other hand, also in the multilayer wiring board, an enhancement in a high frequency characteristic and an improvement in a noise resistance have been highly required with an increase in the speed of a digital signal processing and the spread of mobile communication apparatuses. Consequently, there have been proposed various shield structures (shielding structures) in the multilayer wiring board.

For example, Japanese Patent Laid-Open Publication No. H11(1999)-68313 has disclosed a multilayer wiring board having a semi-coaxial structure in which the circuit pattern of a signal line is surrounded by a shielding layer having a U-shaped section from above and a structure in which a panel-like pattern is formed below the circuit pattern of a signal line via an insulating layer. Moreover, there has also been known a shield structure in which the circuit pattern of a signal line is interposed between upper and lower panel-like patterns via an insulating layer.

In any technique described above, however, a cylindrical shielding layer for covering the whole periphery of the circuit pattern of a signal line is not formed. Therefore, a high frequency characteristic and a noise resistance cannot be obtained sufficiently in a further increase in the density of a wiring board and an increase in the speed of an apparatus. In other words, if the density of the wiring board is increased, electromagnetic coupling between signal patterns is densified. For this reason, the wiring board is apt to be influenced by a noise and a cross talk which are caused by electrostatic induction and electromagnetic induction. Moreover, a characteristic impedance in a high frequency range is apt to be made nonuniform by the influence of electronic components provided around a signal pattern or other patterns.

On the other hand, there has also been known a multilayer wiring board having a coaxial shield structure therein. For example, Japanese Patent Laid-Open Publication No. H7(1995)-99397 has disclosed a method of forming a side wall portion of a coaxial shield structure in which the wedge-shaped groove of an insulating layer is plated to form a wedge-shaped side wall and each layer is then laminated and bonded to connect a wedge-shaped tip portion by pressure. In the structure of the side wall portion, the side wall portion is formed by the plating and the side wall portions are connected to each other by pressure. However, a complicated step is required in the formation of the wedge-shaped trench in the insulating layer, and furthermore, the reliability and durability of connection has a drawback since the side wall portions are connected to each other by pressure.

Moreover, Japanese Patent Laid-Open Publication No. H4(1992)-267586 has disclosed a method of forming a side wall portion of a coaxial shield structure in which a groove for filling a side conductor is formed by photolithography and a thick conductor paste is filled therein and is thus sintered, thereby forming a side conductor and a dielectric. In the structure of the side wall portion, the side wall portion is formed by the conductor paste and the side wall portions are connected to each other through the conductor paste. However, the use of the conductor paste causes a drawback in a conductiveness and a connection reliability at an interface.

It is an object of the present invention to provide a method of manufacturing a multilayer wiring board in which a coaxial shield structure for enhancing a high frequency characteristic and a noise resistance can be formed on the inside by a simple process and equipment. Furthermore, it is another object of the present invention to provide a multilayer wiring board which can be manufactured by such a simple process and equipment and has a high conductive connection reliability and durability.

### SUMMARY OF THE INVENTION

The above-mentioned objects can be attained by the present invention in the following manner.

More specifically, the present invention provides a multilayer wiring board comprising an intermediate wiring layer having a signal pattern, an upper shielding layer formed on an upper side of the intermediate wiring layer via an insulating layer and having an upper shielding portion positioned above the signal pattern, and a lower shielding layer formed on a lower side of the intermediate wiring layer via an insulating layer and having a lower shielding portion positioned under the signal pattern, and

a lower metal wall erected from the lower shielding portion below both sides of the signal pattern and an upper metal wall erected upward from the lower metal wall, the upper shielding portion and the lower shielding portion being conductively connected by the upper metal wall and lower metal wall, thereby forming a cylindrical shielding portion,

wherein the lower metal wall has a protective metal layer formed of another metal having a resistance during etching of a metal constituting the lower metal wall and is bonded to an upper surface of the protective metal layer by plating and is formed by etching, and

wherein the upper metal wall has a protective metal layer formed of another metal having a resistance during etching of a metal constituting the upper metal wall and is bonded to an upper surface of the protective metal layer by plating and is formed by etching.

According to the multilayer wiring board of the present invention, the lower metal wall is erected from the lower shielding portion below both sides of the signal pattern and the upper metal wall is erected there above, thereby conductively connecting the upper shielding portion and the lower shielding portion. Consequently, the cylindrical shielding portion can be formed around the signal pattern by a method in accordance with a build-up method. Therefore, it is possible to provide a multilayer wiring board which is more excellent in a high frequency characteristic and a noise resistance as compared with the conventional art. Furthermore, the protective metal layer is provided below the upper and lower metal walls. Therefore, it is possible to form the metal walls by etching without eroding the lower shielding layer and the intermediate wiring layer. The metal walls are bound to the upper surface of the protective metal layer by plating, so that conductive connection of the interface becomes reliable. The shield structure can be formed by the combination of the etching and the plating and do not particularly require a special step such as laser irradiation.

Moreover, the present invention provides another multilayer wiring board comprising an intermediate wiring layer having a signal pattern and a shielding pattern formed on both sides thereof, an upper shielding layer formed on an upper side of the intermediate wiring layer via an insulating layer and having an upper shielding portion positioned above the signal pattern, and a lower shielding layer formed on a lower side of the intermediate wiring layer via an insulating layer and having a lower shielding portion positioned under the signal pattern, and

an upper metal wall erected from the shielding patterns on both sides and a lower metal wall erected below the shielding pattern, the upper shielding portion and the lower shielding portion being conductively connected by the upper and lower metal layers and the shielding patterns, thereby forming a cylindrical shielding portion,

wherein the lower metal wall has a protective metal layer formed of another metal having a resistance during etching of a metal constituting the metal lower wall and is bonded to an upper surface of the protective metal layer by plating and is formed by etching, and

wherein the upper metal wall has a protective metal layer formed of another metal having a resistance during etching of a metal constituting the metal upper wall and is bonded to an upper surface of the protective metal layer by plating and is formed by etching. According to the multilayer wiring board, furthermore, the shielding pattern is provided between the lower metal wall and the upper metal wall, so that it is possible to conductively connect both layers more reliably.

On the other hand, the present invention provides a method of manufacturing a multilayer wiring board in which an intermediate wiring layer having a signal pattern is formed on an upper side of a lower shielding layer via an insulating layer and an upper shielding layer is then formed on an upper side of the intermediate wiring layer via an insulating layer, comprising the steps of:

(a) forming a lower shielding layer having a lower shielding portion below a portion in which the signal pattern is to be formed;

(b) forming a lower metal wall erected from the lower shielding portion below both sides of the portion in which the signal pattern is to be formed and an insulating layer for exposing the lower metal wall and covering the lower shielding layer;

(c) forming an intermediate wiring layer having shielding patterns provided in contact with upper surfaces of the exposed portions of the lower metal walls on both sides and the signal pattern provided between the shielding patterns;

(d) forming an upper metal wall erected upward from the shielding patterns on both sides and an insulating layer for exposing the upper metal wall and covering the intermediate wiring layer; and

(e) forming an upper shielding layer having an upper shielding portion for at least conductively connecting the exposed portions of the upper metal walls on both sides, thereby forming a cylindrical shielding portion,

wherein the formation of the lower metal wall and the upper metal wall is carried out by the step of coating a whole surface including a non-pattern portion of the lower shielding layer or the intermediate wiring layer with another metal having a resistance during etching of a metal constituting the metal walls, thereby forming a protective metal layer, the step of forming a plated layer of a metal constituting the metal walls over a whole surface of the protective metal layer by electrolytic plating, the step of forming a mask layer in a surface portion of the plated layer in which the metal walls are to be formed, the step of etching the plated layer, and the step of carrying out etching capable of eroding at least the protective metal layer, thereby removing the protective metal layer covering at least the non-pattern portion.

According to the manufacturing method of the present invention, the lower shielding portion, the lower metal wall, the shielding pattern, the upper metal wall and the upper shielding portion are sequentially formed by a method in accordance with a build-up method so that the cylindrical shielding portion can be formed around the signal pattern. Consequently, it is possible to provide a method of manufacturing a multilayer wiring board which is more excellent in a high frequency characteristic and a noise resistance as compared with the conventional art. In that case, the protective metal layer is provided. Therefore, it is possible to form a desirable metal wall in a position in which the mask layer is formed without eroding the lower shielding layer and the intermediate wiring layer during the etching of the plated layer. Moreover, since the protective metal layer is formed over the whole surface, the plated layer can be formed by the electrolytic plating. In addition, the plated layer is not formed in a hole but over the whole surface. Therefore, it is possible to increase a current density and to form a plated layer having a desirable thickness in a short time. The above process is obtained by the combination of the etching and the plating and do not particularly require a special step such as laser irradiation.

Moreover, the present invention provides another method of manufacturing a multilayer wiring board in which an intermediate wiring layer having a signal pattern is formed on an upper side of a lower shielding layer via an insulating layer and an upper shielding layer is then formed on an upper side of the intermediate wiring layer via an insulating layer, comprising a cylindrical shielding portion having steps of:

(a) forming a lower shielding layer having a lower shielding portion below a portion in which the signal pattern is to be formed;

(b) forming a lower metal wall erected from the lower shielding portion below both sides of the portion in which the signal pattern is to be formed and an insulating layer for exposing the lower metal wall and covering the lower shielding layer;

(c′) forming an intermediate wiring layer having the signal pattern provided between the exposed portions of the lower metal walls on both sides;

(d′) forming an upper metal wall erected upward from the exposed portions of the lower metal walls on both sides and an insulating layer for exposing the upper metal wall and covering the intermediate wiring layer; and

(e) forming an upper shielding layer having an upper shielding portion for at least conductively connecting the exposed portions of the upper metal walls on both sides, thereby forming a cylindrical shielding portion,

wherein the formation of the lower metal wall and the upper metal wall is carried out by the step of coating a whole surface including a non-pattern portion of the lower shielding layer or the intermediate wiring layer with another metal having a resistance during etching of a metal constituting the metal walls, thereby forming a protective metal layer, the step of forming a plated layer of a metal constituting the metal walls over a whole surface of the protective metal layer by electrolytic plating, the step of forming a mask layer in a surface portion of the plated layer in which the metal walls are to be formed, the step of etching the plated layer, and the step of carrying out etching capable of eroding at least the protective metal layer, thereby removing the protective metal layer covering at least the non-pattern portion. Also in the manufacturing method, it is possible to provide a method of manufacturing a multilayer wiring board which is more excellent in a high frequency characteristic and a noise resistance in the same manner as described above.

The multilayer wiring board according to the present invention is suitably utilized as a wiring board for a probe card to be used in a semiconductor inspection. In the case in which the multilayer wiring board according to the present invention is to be utilized as the wiring board for the probe card to be used in the semiconductor inspection, particularly, in the uses, it is necessary to cause a signal having a high frequency to pass through a signal line with an increase in the speed of a signal to be used in the semiconductor inspection and the prevention of a cross talk between wirings has become an emergent problem. According to the multilayer wiring board of the present invention in which the cylindrical shielding portion is formed around the signal pattern, the problem can be suitably solved. Thus, the present invention is very useful for the uses.

### BRIEF DESCRIPTION OF THE DRAWINGS

FIG. 1 is a perspective view showing an example of a multilayer wiring board according to the present invention,

FIG. 2 is a perspective view showing another example of the multilayer wiring board according to the present invention,

FIG. 3 is a sectional view showing a further example of the multilayer wiring board according to the present invention,

FIG. 4 is a sectional view showing a further example of the multilayer wiring board according to the present invention, and

FIGS. 5 to 8 are views showing steps (1) to (13) according to an example of a method of manufacturing a multilayer wiring board according to the present invention.

### DETAILED DESCRIPTION OF THE PREFERRED EMBODIMENTS

A preferred embodiment of the present invention will be described below with reference to the drawings in order of a multilayer wiring board and a method of manufacturing the multilayer wiring board.

[Multilayer Wiring Board]

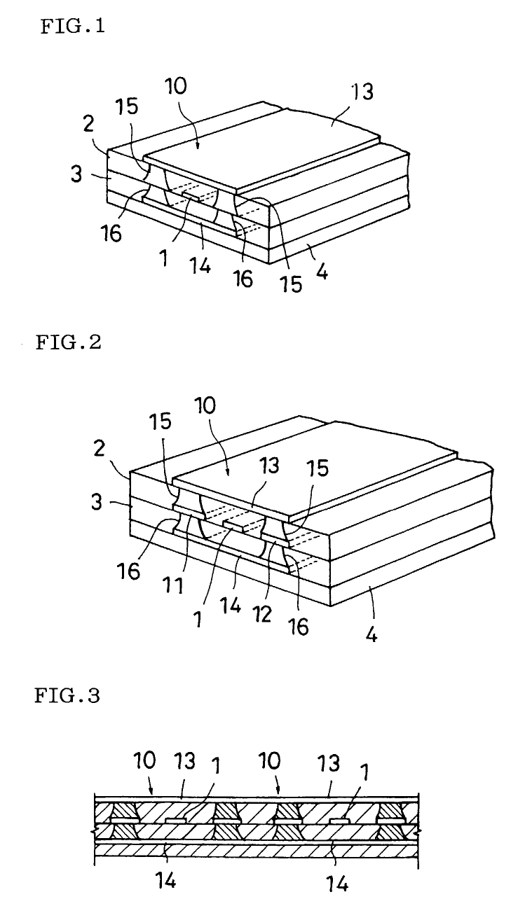

As shown in FIG. 1, a multilayer wiring board according to the present invention comprises an intermediate wiring layer having a signal pattern 1, an upper shielding layer formed on the upper side of the intermediate wiring layer via an insulating layer 2 and having an upper shielding portion 13 positioned above the signal pattern 1, and a lower shielding layer formed on the lower side of the intermediate wiring layer via an insulating layer 3 and having a lower shielding portion 14 positioned under the signal pattern 1. The lower shielding layer is usually formed on the surface of an insulating layer 4 (or a base material).

Moreover, a lower metal wall 16 is erected from the lower shielding portion 14 below both sides of the signal pattern 1 and an upper metal wall 15 is erected above the lower metal wall 16, and the upper shielding portion 13 and the lower shielding portion 14 are conductively connected by the metal walls 15, 16. Consequently, a cylindrical shielding portion 10 is formed.

While another multilayer wiring board according to the present invention has such a structure that shielding patterns 11 and 12 are provided between the lower metal wall 16 and the upper metal wall 15 in the multilayer wiring board, only one of the shielding patterns 11 and 12 may be provided there between in the present invention. As shown in FIG. 2, such a multilayer wiring board comprises an intermediate wiring layer having the signal pattern 1 and the shielding patterns 11 and 12 formed on both sides thereof, an upper shielding layer formed on the upper side of the interlayer wiring layer via the insulating layer 2 and having the upper shielding portion 13 positioned above the signal pattern 1, and a lower shielding layer formed on the lower side of the intermediate wiring layer via the insulating layer 3 and having the lower shielding portion 14 positioned under the signal pattern 1.

Moreover, an upper metal wall 15 is erected from the shielding patterns 11 and 12 on both sides, and a lower metal wall 16 is erected under the shielding patterns 11 and 12. By providing them, the upper shielding portion 13 and the lower shielding portion 14 are conductively connected by the metal walls 15, 16 and the shielding patterns so that the cylindrical shielding portion 10 is formed. It is preferable that the shielding patterns 11 and 12 should have widths which are almost equal to those of the bottom portions of the lower metal wall 16 and the upper metal wall 15, and may be formed more widely. In that case, the lower metal wall 16 and the upper metal wall 15 are formed in the portions of the shielding patterns 11 and 12 on both sides which are the closest to the signal pattern 1. Accordingly, if the shielding patterns 11 and 12, the upper shielding portion 13, the lower shielding portion 14, the upper metal wall 15 and the lower metal wall 16 in the present invention are conductors capable of forming the cylindrical shielding portion 10, any material, structure, shape and the like may be used. The upper shielding layer and the lower shielding layer include the upper shielding portion 13 or the lower shielding portion 14 and may also include another wiring pattern or the like.

In the foregoing, the signal pattern 1 and the cylindrical shielding portion 10 are formed linearly or non-linearly, and it is preferable that the sectional shape of a shield structure constituted by the signal pattern 1 and the cylindrical shielding portion 10 should be uniform in order to cause a characteristic impedance in a high frequency range to be even. Moreover, the cylindrical shielding portion 10 may be formed on the signal pattern 1 wholly or partially.

At least one shield structure constituted by the signal pattern 1 and the cylindrical shielding portion 10 is provided in the multilayer wiring board. In the case in which a plurality of shield structures is provided, each of them is provided in the same plane or different planes and is formed independently or is coupled partially.

In an example shown in FIG. 3, a plurality of shield structures is provided in the same plane, and the upper shielding portion 13 and the lower shielding portion 14 constituting the cylindrical shielding portion 10 are formed of a common metal panel between the adjacent shield structures. Moreover, the lower metal wall 16 and the upper metal wall 15 may be shared between the adjacent shield structures.

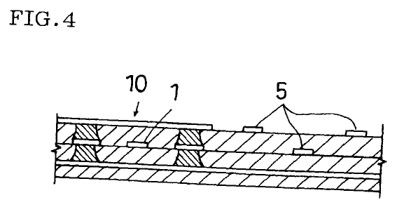

Moreover, the multilayer wiring board may have a wiring pattern 5 in portions other than the shield structure, for example, the upper shielding layer, the intermediate wiring layer, the lower shielding layer and the like as shown in FIG. 4. A double-sided multilayer wiring board built up on both surfaces of a substrate may be formed. In that case, the central substrate side is assumed to be the lower side and the present invention will be thus described.

While the signal pattern 1 and the cylindrical shielding portion 10 are formed of a conductor such as a metal or a conductive coating film, a material which will be described in the following manufacturing method is preferred for a specific material. According to the following manufacturing method, the lower metal wall 16 and the upper metal wall 15 have structures in which at least one kind of metal or the like is laminated.

While the multilayer wiring board according to the present invention can be suitably manufactured by the following manufacturing method according to the present invention, it can also be manufactured by a method of bonding a plurality of layers patterned previously through heating and pressurization and the like.

[Method of Manufacturing Multilayer Wiring Board]

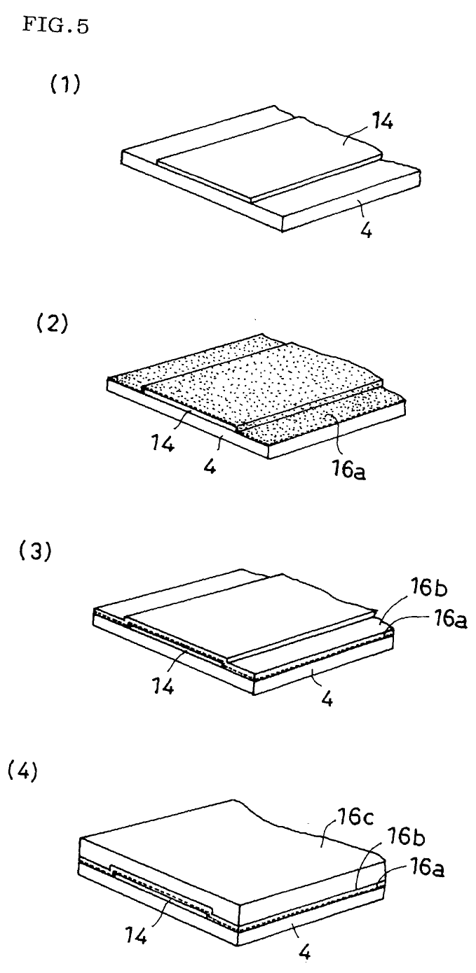

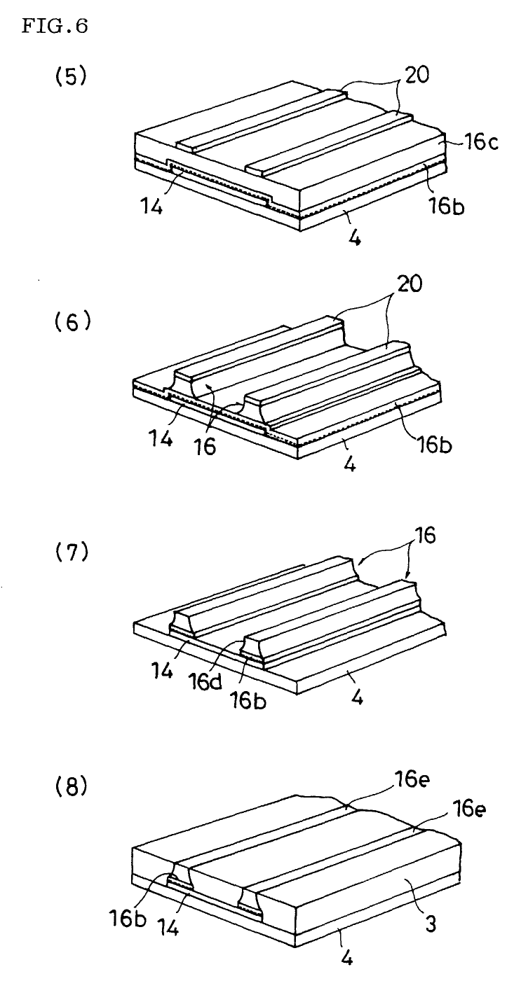

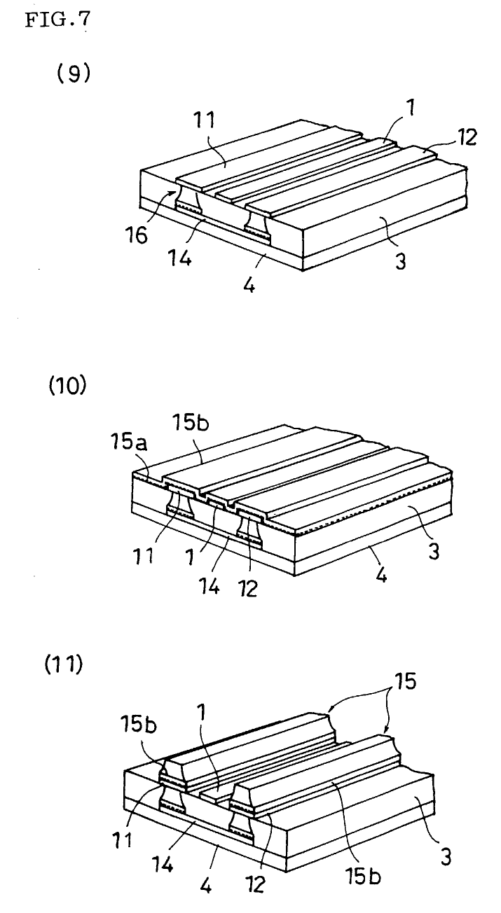

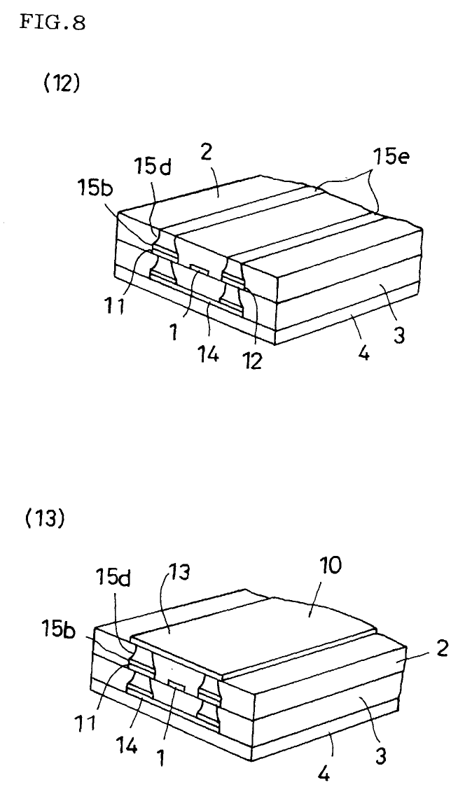

The method of manufacturing a multilayer wiring board according to the present invention comprises the step of forming an intermediate wiring layer having a signal pattern on the upper side of a lower shielding layer via an insulating layer and then forming an upper shielding layer on the upper side of the intermediate wiring layer via an insulating layer. As shown in FIGS. 5 to 8, the manufacturing method comprises a step (a) of forming a lower shielding layer having the lower shielding portion 14 below a portion in which a signal pattern is to be formed (see FIG. 5(1)), a step (b) of forming the lower metal wall 16 erected from the lower shielding portion 14 below both sides of the portion in which the signal pattern is to be formed and the insulating layer 3 for exposing the lower metal wall 16 and covering the lower shielding layer (see FIG. 6(8)), a step (c) of forming an intermediate wiring layer having the shielding patterns 11 and 12 in contact with the upper surfaces of exposed portions 16e of the lower metal walls on both sides and the signal pattern 1 provided there between (see FIG. 7(9)), a step (d) of forming the upper metal wall 15 erected upward from the shielding patterns 11 and 12 on both sides and the insulating layer 2 for exposing the upper metal wall 15 and covering the intermediate wiring layer (see FIG. 8(12)), and a step (e) of forming an upper shielding layer having the upper shielding portion 13 for at least conductively connecting the exposed portions 15e of the upper metal walls on both sides (see FIG. 8(13)). Consequently, the multilayer wiring board having the cylindrical shielding portion 10 is manufactured.

Moreover, another manufacturing method according to the present invention comprises a step (c′) of forming an intermediate wiring layer having the signal pattern 1 provided between the exposed portions 16e of the lower metal walls on both sides in place of the step (c), and a step (d′) of forming the upper metal wall 15 erected upward from the exposed portions 16e of the lower metal walls on both sides and the insulating layer 2 for exposing the upper metal wall 15 and covering the intermediate wiring layer in place of the step (d).

Also in any of the manufacturing methods, it is preferable that the lower metal wall 16 and the upper metal wall 15 should be formed by the following method.

First of all, as shown in FIG. 5(1), the lower shielding portion 14 is patterned on the base material 4. In that case, any pattern forming method may be used. For example, it is possible to carry out by a method using an etching resist, a method using a resist for pattern plating or the like. A base material comprising various reactive curing resins such as a polyimide resin and glass fiber can be used for the base material 4. Moreover, copper, nickel, tin or the like can usually be used as a metal constituting the lower shielding portion 14.

As shown in FIG. 5(2), next, nonelectrolytic plating is carried out over the whole surface including the non-pattern portion of the lower shielding layer having the lower shielding portion 14, thereby forming a lower conductive layer 16a. A plating solution such as copper, nickel or tin is usually used for the nonelectrolytic plating, and these metals may be identical to or different from a metal constituting the lower shielding portion 14. The plating solution for the nonelectrolytic plating is well known corresponding to various metals and various plating solutions have been put on the market. Prior to the nonelectrolytic plating, a plating catalyst such as palladium may be deposited.

As shown in FIG. 5(3), next, electrolytic plating is carried out over the whole surface of the lower conductive layer 16a to form a protective metal layer 16b in order to coat the whole surface including the non-pattern portion of the lower shielding layer with the protective metal layer 16b. In that case, another metal having a resistance during the etching of a metal constituting the lower metal wall 16 is used for a metal constituting the protective metal layer 16b. More specifically, in the case in which the metal constituting the lower metal wall 16 is copper, gold, silver, zinc, palladium, ruthenium, nickel, rhodium, a lead—tin based solder alloy, a nickel—gold alloy or the like is used for another metal constituting the protective metal layer 16b. The present invention is not restricted to a combination of the metals but any combination of a metal which can be subjected to the electrolytic plating and another metal having a resistance during the etching can be used. The electrolytic plating can be carried out by a well-known method.

More specifically, at the step of coating the whole surface including the non-pattern portion of the lower shielding layer or the intermediate wiring layer with another metal having a resistance during the etching of the metal constituting the metal wall to form the protective metal layer in the present invention, the coating with the protective metal layer 16b may be carried out with the lower conductive layer 16a or the like provided as described above or may be directly carried out without the lower conductive layer 16a or the like provided. By carrying out the electrolytic plating over the whole surface of the lower shielding layer patterned after performing the nonelectrolytic plating over the whole surface of the base material 4 to form the lower conductive layer 16a, the protective metal layer 16b may be formed. Moreover, it is also possible to form the lower conductive layer by sputtering or the like.

As shown in FIG. 5(4), next, the plated layer 16c of the metal constituting the metal wall is formed over the whole surface of the protective metal layer 16b by the electrolytic plating. While copper, nickel or the like is usually used for the metal, it may be identical to or different from the metal constituting the lower shielding portion 14. For example, the plated layer 16c has a thickness of 20 to 200 μm. Thus, the plated layer 16c is formed over the whole surface by the electrolytic plating. Therefore, the height of the plated layer 16c is almost equal so that a metal wall having an almost uniform height can be formed rapidly.

As shown in FIG. 6(5), then, a mask layer 20 is formed in the surface portion of the plated layer 16c in which the metal wall is to be formed. The mask layer 20 can be formed by screen printing or photolithography, for example. The width of the mask layer 20 is determined depending on the width of the metal wall and is 100 to 300 μm or more, for example.

As shown in FIG. 6(6), thereafter, the plated layer 16c is subjected to etching. In that case, when the amount of erosion by the etching is too large, the metal wall to be formed is thinned (undercut is increased) so that subsequent steps are impeded. To the contrary, when the amount of erosion is too small, the plated layer 16c remains in the non-pattern portion so that a short circuit is caused. Accordingly, it is preferable that the degree of the erosion by the etching should be set as shown in FIG. 6(6) or within such a range as to be increased or decreased slightly.

Examples of the etching method include an etching method using various etching solutions depending on the type of each of the metals constituting the plated layer 16c and the protective metal layer 16b. For example, in the case in which the plated layer 16c is copper and the protective metal layer 16b is the above-mentioned metal (including a metal based resist), an alkali etching solution put on the market, ammonium peroxodisulfate, hydrogen peroxide/sulfuric acid or the like can be used.

As shown in FIG. 6(7), subsequently, the mask layer 20 is removed. For the removal, drug removal, peeling removal and the like can be properly selected depending on the type of the mask layer 20. For example, photosensitive ink formed by the screen printing is removed with an agent such as alkali.

Before or after the mask layer 20 is removed, etching capable of eroding at least the protective metal layer 16b is carried out to remove the protective metal layer 16b coating at least the non-pattern portion. For the removal of the protective metal layer 16b, the etching capable of carrying out the erosion is usually performed. Examples of the etching method include an etching method using a different etching solution from the foregoing. If a chloride etching solution is used, both a metal based resist and copper are eroded. For this reason, other etching solutions are preferably used. More specifically, in the case of the combination of the metals described above, an etching solution f or solder peeling has been put on the market. It is preferable to use an acid based etching solution such as a nitric acid, sulfuric acid or cyan based etching solution.

Next, the lower conductive layer 16a remaining in the non-pattern portion is removed by soft etching. The soft etching is carried out in order to prevent the metal wall or the like from being eroded excessively. For the soft etching method, an etching solution is used in a low concentration or is used on the gentle etching conditions.

As shown in FIG. 6(8), then, an insulating material for forming the insulating layer 3 is coated and the cured insulating material is then ground and polished, thereby forming the lower metal wall 16 erected from the lower shielding portion 14 below both sides of the portion in which the signal pattern is to be formed and the insulating layer 3 for exposing the lower metal wall 16 and covering the lower shielding layer (b step). A reactive curing resin such as a liquid polyimide resin which is excellent in an insulating property and is inexpensive can be used for the insulating material, for example. It is preferable that the resin should be coated to be thicker than the height of the lower metal wall 16 and be then cured by heating or light irradiation through various methods. A hot press and various coaters are used for the coating method. Moreover, examples of the grinding method include a method using a grinding device in which a plurality of hard rotating blades formed of diamond or the like is provided in the radial direction of a rotating plate. It is possible to flatten the upper surface of a fixed and supported wiring board while rotating and moving the hard rotating blades along the upper surface. Moreover, examples of the polishing method include a method of lightly carrying out polishing by a belt sander, buffing or the like.

As shown in FIG. 7(9) , thereafter, the intermediate wiring layer having the shielding patterns 11 and 12 provided in contact with the upper surfaces of the exposed portions 16e of the lower metal walls 16 on both sides and the signal pattern 1 provided there between are formed (c step). The intermediate wiring layer can be formed with a predetermined pattern by forming a predetermined mask using photolithography and carrying out etching, for example, in the same manner as the lower shielding layer.

As shown in FIGS. 7(10) to 8(12), moreover, the upper metal wall 15 erected upward from the shielding patterns 11 and 12 on both sides and the insulating layer 2 for exposing the upper metal wall 15 and covering the intermediate wiring layer are formed in the same manner as described above (d step). More specifically, nonelectrolytic plating is carried out over the whole surface including the non-pattern portion of the intermediate wiring layer to form the lower conductive layer 15a, and electrolytic plating is carried out over the whole surface to form the protective metal layer 15b (see FIG. 7(10)). Next, the metal plated layer constituting the metal wall is formed over the whole surface of the protective metal layer 15b by the electrolytic plating and the mask layer is formed in the surface portion of the plated layer in which the metal wall is to be formed, and the plated layer is then etched. Subsequently, the mask layer is removed and etching capable of eroding at least the protective metal layer 15b is carried out there before or thereafter to remove the protective metal layer 15b covering at least the non-pattern portion, and the remaining lower conductive layer 15a is removed by soft etching (see FIG. 7(11)). Next, an insulating material for forming the insulating layer 2 is coated and the cured insulating material is then grounded and polished (see FIG. 8(12)).

As shown in FIG. 8(13), then, the upper shielding layer having the upper shielding portion 13 for at least conductively connecting the exposed portions 15e of the upper metal walls 15 on both sides is formed (e step). Also at this step, it is possible to form the lower shielding layer with a predetermined pattern by forming a predetermined mask using the photolithography and carrying out etching, for example, in the same manner as the lower shielding layer.

[Another Embodiment]

(1) In the formation of the lower metal wall and the upper metal wall, the present invention may be carried out by the step of coating the pattern portion of the lower shielding layer with a conductor having a resistance during the etching of a metal constituting the metal wall, thereby forming a conductor layer, the step of forming a metal plated layer constituting the metal wall over the almost whole surface including the conductor layer, the step of forming a mask layer in the surface portion of the plated layer in which the metal wall is to be formed, and the step of etching the plated layer.

(2) In the formation of the lower metal wall and the upper metal wall, moreover, the present invention may be carried out by the step of forming a plated layer of a metal which is different from the lower shielding layer and constitutes the metal wall over the almost whole surface including the non-pattern portion of the lower shielding layer, the step of forming a mask layer in the surface portion of the plated layer in which the metal wall is to be formed, and the step of etching the plated layer with an etching agent which erodes the lower shielding layer with difficulty.

[Embodiment of Wiring Board for Probe Card]

Next, description will be given to an embodiment in which the multilayer wiring board according to the present invention is utilized as a wiring board for a probe card to be used in a semiconductor inspection.

In general, the probe card has such a structure that a needle formed of tungsten or the like to be connected to the bonding pad of a semiconductor device which has a size of approximately 50 to 250 μmφ is fixed with a resin, a needle base is connected, by soldering, to a pad provided on the multilayer wiring board, and a signal line is wired in the board and is electrically connected to a tester through a pad provided on the outer periphery of the board. It is preferable that a coaxial needle should be used for the needle and the length of the needle should be reduced as much as possible in order to be adapted to a test for a high-speed signal. By causing the wiring board to have such a structure that the signal line is completely shielded as in the present invention, it is possible to correspond to the high-speed test signal. Therefore,the multilayer wiring board according to the present invention is very useful for the wiring board for the probe card.

What is claimed is:

1. A multilayer wiring board comprising an intermediate wiring layer having a signal pattern, an upper shielding layer formed on an upper side of the intermediate wiring layer via an insulating layer and having an upper shielding portion positioned above the signal pattern, and a lower shielding layer formed on a lower side of the intermediate wiring layer via an insulating layer and having a lower shielding portion positioned under the signal pattern, and
a lower metal wall erected from the lower shielding portion below both sides of the signal pattern and an upper metal wall erected upward from the lower metal wall, the upper shielding portion and the lower shielding portion being conductively connected by the upper metal wall and lower metal wall, thereby forming a cylindrical shielding portion,
wherein the lower metal wall has a protective metal layer formed of another metal having a resistance during etching of a metal constituting the lower metal wall and is bonded to an upper surface of the protective metal layer by plating and is formed by etching, and
wherein the upper metal wall has a protective metal layer formed of another metal having a resistance during etching of a metal constituting the upper metal wall and is bonded to an upper surface of the protective metal layer by plating and is formed by etching.

2. The multilayer wiring board according to claim 1, wherein the protective metal layer is formed by the plating.

3. The multilayer wiring board according to claim 1, wherein the multilayer wiring board is utilized as a wiring board for a probe card to be used in a semiconductor inspection.

4. A multilayer wiring board comprising an intermediate wiring layer having a signal pattern and a shielding pattern formed on both sides thereof, an upper shielding layer formed on an upper side of the intermediate wiring layer via an insulating layer and having an upper shielding portion positioned above the signal pattern, and a lower shielding layer formed on a lower side of the intermediate wiring layer via an insulating layer and having a lower shielding portion positioned under the signal pattern, and
an upper metal wall erected from the shielding patterns on both sides and a lower metal wall erected below the shielding pattern, the upper shielding portion and the lower shielding portion being conductively connected by the upper and lower metal walls and the shielding patterns, thereby forming a cylindrical shielding portion,
wherein the lower metal wall has a protective metal layer formed of another metal having a resistance during etching of a metal constituting the metal lower wall and is bonded to an upper surface of the protective metal layer by plating and is formed by etching, and
wherein the upper metal wall has a protective metal layer formed of another metal having a resistance during etching of a metal constituting the metal upper wall and is bonded to an upper surface of the protective metal layer by plating and is formed by etching.

5. The multilayer wiring board according to claim 4, wherein the protective metal layer is formed by the plating.

6. The multilayer wiring board according to claim 4, wherein the multilayer wiring board is utilized as a wiring board for a probe card to be used in a semiconductor inspection.

7. A method of manufacturing a multilayer wiring board in which an intermediate wiring layer having a signal pattern is formed on an upper side of a lower shielding layer via an insulating layer and an upper shielding layer is then formed on an upper side of the intermediate wiring layer via an insulating layer, comprising the steps of:
(a) forming a lower shielding layer having a lower shielding portion below a portion in which the signal pattern is to be formed;
(b) forming a lower metal wall erected from the lower shielding portion below both sides of the portion in which the signal pattern is to be formed and an insulating layer for exposing the lower metal wall and covering the lower shielding layer;
(c) forming an intermediate wiring layer having shielding patterns provided in contact with upper surfaces of the exposed portions of the lower metal walls on both sides and the signal pattern provided between the shielding patterns;
(d) forming an upper metal wall erected upward from the shielding patterns on both sides and an insulating layer for exposing the upper metal wall and covering the intermediate wiring layer; and
(e) forming an upper shielding layer having an upper shielding portion for at least conductively connecting the exposed portions of the upper metal walls on both sides, thereby forming a cylindrical shielding portion,
wherein the formation of the lower metal wall and the upper metal wall is carried out by the step of coating a whole surface including a non-pattern portion of the lower shielding layer or the intermediate wiring layer with another metal having a resistance during etching of a metal constituting the metal walls, thereby forming a protective metal layer, the step of forming a plated layer of a metal constituting the metal walls over a whole surface of the protective metal layer by electrolytic plating, the step of forming a mask layer in a surface portion of the plated layer in which the metal walls are to be formed, the step of etching the plated layer, and the step of carrying out etching capable of eroding at least the protective metal layer, thereby removing the protective metal layer covering at least the non-pattern portion.

8. The method of manufacturing a multilayer wiring board according to claim 7, wherein the protective metal layer is formed by plating.

9. A method of manufacturing a multilayer wiring board in which an intermediate wiring layer having a signal pattern is formed on an upper side of a lower shielding layer via an insulating layer and an upper shielding layer is then formed on an upper side of the intermediate wiring layer via an insulating layer, comprising the steps of:
(a) forming a lower shielding layer having a lower shielding portion below a portion in which the signal pattern is to be formed;
(b) forming a lower metal wall erected from the lower shielding portion below both sides of the portion in which the signal pattern is to be formed and an insulating layer for exposing the lower metal wall and covering the lower shielding layer;
(c′) forming an intermediate wiring layer having the signal pattern provided between the exposed portions of the lower metal walls on both sides;
(d′) forming an upper metal wall erected upward from the exposed portions of the lower metal walls on both sides and an insulating layer for exposing the upper metal wall and covering the intermediate wiring layer; and
(e) forming an upper shielding layer having an upper shielding portion for at least conductively connecting the exposed portions of the upper metal walls on both sides, thereby forming a cylindrical shielding portion,
wherein the formation of the lower metal wall and the upper metal wall is carried out by the step of coating a whole surface including a non-pattern portion of the lower shielding layer or the intermediate wiring layer with another metal having a resistance during etching of a metal constituting the metal walls, thereby forming a protective metal layer, the step of forming a plated layer of a metal constituting the metal walls over a whole surface of the protective metal layer by electrolytic plating, the step of forming a mask layer in a surface portion of the plated layer in which the metal walls are to be formed, the step of etching the plated layer, and the step of carrying out etching capable of eroding at least the protective metal layer, thereby removing the protective metal layer covering at least the non-pattern portion.

10. The method of manufacturing a multilayer wiring board according to claim 9, wherein the protective metal layer is formed by plating.
